(19) United States
(12) Patent Application Publication
(10) Pub. No.: US 2025/0159983 A1
(43) Pub. Date: May 15, 2025

(54) Active Wafer-Scale Reconfigurable Logic Fabric for AI and High-Performance Embedded Computing

(71) Applicant: Massachusetts Institute of Technology, Cambridge, MA (US)

(72) Inventors: Brian Tyrrell, Madison, AL (US); Albert Reuther, Westford, MA (US); Rabindra Das, Lexington, MA (US); Vitaliy Gleyzer, Westford, MA (US)

(21) Appl. No.: 18/883,881

(22) Filed: Sep. 12, 2024

Related U.S. Application Data
(60) Provisional application No. 63/548,474, filed on Nov. 14, 2023.

(51) Int. Cl. H01L 27/118

(52) U.S. Cl. CPC H10D 84/907; H10D 84/975

(57) ABSTRACT

A novel active and passive wafer-scale fabric is disclosed that allows for the integration of very-large-scale integrated circuits (ICs) with hundreds of closely-spaced bare-die chips such as memory, GPUs, FPGAs and AI accelerators into a single wafer. The wafer-scale logic fabric allows the tiling of known good chips to make systems that perform as a single-chip monolithic device, despite comprising several smaller heterogeneous chips. This approach enables higher bandwidth and lower connectivity loss than conventional circuit board packaging, which is especially critical for AI computing and signal/image processing applications. Further, it also allows for multiple levels of high-density connections, since this architecture allows wiring between chips to be as small as the wiring within a chip. This wafer-scale platform combined with heterogeneous IP block/chiplets and μ-bump integration produces a chip-like wiring for the wafer-scale heterogeneous multi-chip system where part of chip can be removed or reconfigured.

This application claims priority from U.S. Provisional Patent Application Ser. No. 63/548,474, filed Nov. 14, 2023, the disclosure of which is incorporated herein by reference in its entirety.

This invention was made with government support under FA8702-15-D-0001 awarded by the U.S. Air Force. The government has certain rights in the invention.

### BACKGROUND

With the advent of advanced high-fidelity sensors and intelligent systems, processing requirements on embedded platforms such as satellites, remotely piloted aircraft and unmanned underwater vehicles, have increased drastically. The designs for these next generation platforms are consistently trading off between enabling more computational capability and their overall size, weight and power (SWaP). Nowhere is this trade-off friction more evident than in embedded processing for small and micro satellites. For such satellites, the best performing processor is modestly more capable than terrestrial processing technologies from over a decade ago. In order to keep up with the demanding computational requirements, these embedded processors must able to handle workloads that are traditionally performed using a cluster of high-performance, server-grade computers while fitting into volume and power budget constraints which are an order of magnitude smaller. These types of compute densities are impossible to achieve using traditional printed circuit board (PCB) integration techniques.

High-density wafer-scale computing has tremendous potential for accelerating real-life computational workloads. But producing such wafer-scale computing integrating systems is very challenging. It is particularly difficult to produce full wafers with adequate quality and reliability for viability. Current complex integrated systems are comprised of several integrated chiplets, but that is far from the wafer-scale.

In the past few years, small-scale chiplet integration has been enabling CPUs to reach a dizzying number of compute cores per socket. AMD has taken advantage of this technology for several years, and very recently Intel has also taken advantage of it as well. While wafer-scale computational systems have been attempted several times over the past decades, only recently has any success been realized by Cerebras in their Wafer Scale Engine (WSE). Commercially, the current state of the art is being led by Cerebras and CEA-Leti, which are both static inter-chip/core solutions.

The key advantage for wafer-scale integration is the dramatic reduction in volume. In contrast to current embedded processing systems where the chip density is limited by thermal dissipation and input/output (IO) density of the PCB technology, the wafer substrate can provide unparalleled IO density for inter-chip communication while substantially improving thermal and electrical characteristics. These key factors allow for chips to be placed much closer together, which leads to reduction of the overall system volume of up to 80 percent as compared to existing state-of-the-art solutions. Furthermore, since the energy required to transmit a bit of information is highly dependent on the transmission distance, the close proximity of the processing chips can enable significant power efficiency improvements for inter-chip communication, which can then translate to significant reduction in overall system power. With this technology, a full 42 U rack of processing equipment may be reduced into a single 8 U server.

High-density wafer-scale computing has tremendous potential for accelerating real-life computational workloads; however, there are still a number of challenges to realizing this capability; among them are:
Current chiplets are not usually designed to be compatible since they are designed by different companies for different applications. Therefore, putting multiple chiplets together onto a single wafer involving multiple protocols and interconnects is an integration challenge.
Because of the highly integrated nature of the platform, the ability to deal with failed components or interconnects is very challenging. In case of failure or manufacturing defect, the entire wafer may need to be scrapped.
Even though wafer-scale integration brings the processors and the working memory closer together, it doesn't eliminate the need for constant communication between processors and memory for high intensity data workloads. The latency and throughput requirements for this back-and-forth communication can be a significant bottleneck for many real-life applications.

Therefore, it would be beneficial if there was a wafer-scale platform that addressed these issues.

### SUMMARY

A novel active and passive wafer-scale fabric is disclosed that allows for the integration of very-large-scale integrated circuits (ICs) with hundreds of closely-spaced bare-die chips such as memory, GPUs, FPGAs and AI accelerators integrated into a single wafer. The wafer-scale logic fabric allows the tiling of known good chips to make systems that perform as a single-chip monolithic device, despite comprising several smaller heterogeneous chips. This approach enables higher bandwidth and lower connectivity loss than conventional circuit board packaging, which is especially critical for AI computing and signal/image processing applications. Further, it also allows for multiple levels of high-density connections, since this architecture allows wiring between chips to be as small as the wiring within a chip. This wafer-scale platform combined with heterogeneous IP block/chiplets and μ-bump integration produces a chip-like wiring for the wafer-scale heterogeneous multi-chip system where part of the chip may be removed or reconfigured.

According to one embodiment, a multi-layer wafer-scale fabric is disclosed. The multi-layer wafer-scale fabric comprises two or more vertically disposed sections, each of the sections having first and second opposing surfaces and including: at least one insulating layer; and a plurality of electrical connections extending between the first and second opposing surfaces; wherein a first section comprises one or more active layers; and wherein at least one of the two or more sections includes one or more repairable routing layers. In some embodiments, the one or more active layers comprise semiconductor layers. In some embodiments, the one or more active layers comprise superconductor layers. In some embodiments, a first active layer comprises at least one transistor layer provided as a reconfigurable logic fabric and/or dynamically reconfigurable logic fabric. In certain embodiments, the reconfigurable logic fabric further comprises at least one of power supplies, clock generators, output amplifiers, voltage regulators, resonators, waveguides, and photonic circuits. In some embodiments, at least one section comprises under bump metal (UBM) provided as a through oxide via (TOV) structure or a through insulator via (TIV) structure. In some embodiments, the one or more active layers comprise a gate array and/or look up tables and/or D flip flops and/or a reconfigurable interconnect. In some embodiments, at least one through via or a through silicon via (TSV) is provided as an electrical connection between the sections. In some embodiments, the one or more active layers comprise at least one layer provided junction as reconfigurable superconducting logic fabric and/or dynamically reconfigurable logic fabric. In certain embodiments, the superconducting logic fabric comprises at least one of single flux quantum (SFQ), adiabatic quantum-flux-parametron (AQFP), quantum flux parametron (QFP), power supplies, clock generators, output amplifiers, voltage regulators, resonators, waveguides, or photonic circuits. In some embodiments, a size of the multi-layer wafer-scale fabric ranges from below reticle size to reticle size to stitched reticle to full real estate of wafer. In some embodiments, the one or more active layers include a lithographically reconfigured circuit to compensate misalignment and modify routing.

According to another embodiment, a wafer-scale package is disclosed. The wafer-scale package comprises a base circuitized substrate including a first circuit and a plurality of electrical conductors; a first integrated circuit including a second circuit and a plurality of electrical conductors; a wafer-scale fabric including first and second opposing surfaces positioned between the base circuitized substrate and the first integrated circuit, the wafer-scale fabric electrically interconnecting selected ones of the electrical conductors of the first circuit with corresponding selected ones of the electrical conductors of the second circuit, the wafer-scale fabric including a reconfigurable logic fabric; and at least one through Silicon via (TSV) included within the wafer-scale fabric wherein the TSV is electrically coupled to the first and second opposing surfaces of the wafer-scale fabric. In some embodiments, the base circuitized substrate is an interposer module, a multi-chip module (MCM), a Package substrate or a printed circuit board (PCB). In some embodiments, the reconfigurable logic fabric includes at least one transistor or junction layer. In some embodiments, an electrical interconnect is provided from a material or combination of materials having single and/or multiple melt temperatures. In certain embodiments, the electrical interconnect is provided as a solder and/or metal ball, sphere, pillar, or micro-bump. In some embodiments, the wafer-scale fabric is coupled to the first integrated circuit using a flip-chip bonding process, and at least one interconnect structure is provided as a metal or solder coated metal micro-bump and controls a distance and interconnect pitch between the wafer-scale fabric and integrated circuit during the flip-chip bonding process. In some embodiments, the first integrated circuit includes at least a heat sink, micro-channel, impingement cooling or micro-jet cooling for efficient heat dissipation. In some embodiments, the base circuitized substrate is coupled to the wafer-scale fabric using a second interconnect structure having a second, different melt temperature and larger interconnect pitch. In some embodiments, the wafer-scale package includes a second integrated circuit having a third circuit thereon including a plurality of electrical conductors; wherein the second integrated circuit is electrically coupled to the wafer-scale fabric. In certain embodiments, the second integrated circuit is electrically coupled to the first integrated circuit through the wafer-scale fabric.

### BRIEF DESCRIPTION OF THE DRAWINGS

For a better understanding of the present disclosure, reference is made to the accompanying drawings, in which like elements are referenced with like numerals, and in which:

FIG. 1 shows the wafer-scale reconfigurable logic fabric;

FIG. 2 shows a side view of a package that includes the wafer-scale reconfigurable logic fabric;

FIG. 3 shows the assembled package that includes the wafer-scale reconfigurable logic fabric;

FIGS. 4A-4D show the sequence to fabricate the circuitry in the wafer;

FIGS. 4E-4F show two embodiments that illustrate the stacking of layers in a wafer;

FIG. 5 shows the metal layers formed on the circuitry;

FIG. 6 shows a wafer with a defect;

FIG. 7 shows a potential remedy for the defect in FIG. 6;

FIG. 8 shows the interconnection between the wafer and a chiplet;

FIG. 9 shows an assembly including the wafer, interposers and chiplets; and

FIG. 10 shows an AI based decision tree to fabricate a large area integrated circuit.

### DETAILED DESCRIPTION

As used herein, the term “reconfiguration” in the wafer-scale fabric is used to describe an adaptive reconfiguration as well as operational reconfiguration. For adaptive reconfiguration, a testable wafer fabric may be lithographically reconfigured to eliminate and/or minimize defects for 2D, 2.5D, 3D and heterogeneous integration. In one example, lithographically reconfigured circuits may be used to compensate for misalignment and to modify routing. For operational reconfiguration, the logic circuit may be reconfigured (such as electronically via programmable switches) to eliminate and/or minimize performance impact from a non-functional circuit. Operational reconfiguration is used to describe a statically or dynamically reconfigured circuit.

Typically, the conventional approach to implementing computing hardware is to place integrated circuits comprising active circuitry onto a predominantly passive printed circuit board (PCB) or multi-chip module (MCM). The role of the PCB or MCM is simply to provide the fixed wiring between the active components. In contrast, the present approach replaces the integration substrate (i.e. the PCB or MCM) with a large scale (e.g. wafer scale) reconfigurable routing fabric. To implement this fabric, programmable switch matrix circuits, programmable logic blocks, fan out circuits, and other resources are incorporated into the integration substrate. These may be referred to as integration substrate resource circuits for reconfiguration.

In one embodiment, the present invention has a set of computational active circuits and memory circuits that implement the computation function, a set of integration substrate resource circuits (also active) that are part of the claimed reconfigurable integration substrate, and the metal routing wiring layers that connect them. This allows the wiring provided by the integration substrate to be statically or dynamically reconfigured. For example:
In the case of a defect in the metal wiring, the integration substrate resource circuits may be configured to bypass the defect.
In the case in which a particular computational active circuit needs to be more directly connected to a particular memory circuit, the integration substrate resource circuits may be reconfigured to create a more direct connection between those circuit modules.
In the case in which a particular computational active circuit is incompatible with another computational active circuit, the integration substrate resource circuits may be used to create an adapter between the two.
In the case where a particular computational active circuit in an overall design is to be replaced with a different computational active circuit, it is not necessary to redesign the overall integration substrate and the broader computational circuit; rather, the integration substrate resource circuits may be configured so as to compensate for any changes required to support the change of components.

In one embodiment, the integration substrate resource circuit may use an electronic and/or photonic circuit that can be electronically and/or optically reconfigured to keep the circuit operational and functional. In some embodiments, the integration substrate resource circuit may use dynamically and/or partially dynamically reconfigurable logic. In another embodiment, the integration substrate resource circuit may use memory elements, such as static memory (SRAM) or nonvolatile RAM (NVRAM).

As used herein, the term “microbump” in the wafer-scale fabric is used to describe a metal including one or more of tin-lead, bismuth-tin, bismuth-tin-iron, tin, indium, tin-indium, indium-gold, tin-indium-gold, tin-silver, tin-gold, gold, copper, tin-silver-zinc, tin-silver-zinc-copper, tin-bismuth-silver, tin-copper, tin-copper-silver, tin-indium-silver, tin-antimony, tin-zinc, tin-zinc-indium, copper-based solders, and alloys thereof. The metals may change forms (e.g., from a solid to a liquid) during a bonding or during post bonding annealing or reflow process.

As used herein, the term “wafer-scale fabric” is used to describe a single or multilayer structure including a number of active or passive semiconductor, superconductor, electromechanical and/or photonic components, the structure capable of performing at least part of the functional operations (i.e., semiconductor system performance) of a semiconductor structure. Wafer-scale fabric layers are typically fabricated separately on Silicon on insulator (SOI) substrates or bulk Silicon (Si) substrates. Additionally, each device layer may include at least one interconnect and one or more of active Si, Gallium nitride (GaN) and III-V field-effect transistors (FETs).

Example fabric layers may include complementary metal-oxide semiconductor (CMOS) integrated circuits having a pair of transistors, one using electrons and the other electron holes. Silicon (Si) and/or Germanium (Ge) semiconductor materials may be used to fabricate device layers having silicon transistors in high performance applications, for example. Alternative semiconductor materials such as Gallium Nitride (GaN) and Silicon Carbide (SiC) may also be used as they tend to cope much better at higher temperatures (e.g., Si for electronics and compound semiconductors for photonics). Silicon dioxide (SiO₂) and hafnium dioxide (HfO₂) may be used as insulator materials or structures within transistors in device layers. Additionally, III-V compound semiconductors, particularly those containing Indium such as Indium Arsenide and Indium Antimonide combined with germanium-rich transistors (e.g., nfinFETs with fins that are 5 nm wide or less), may be used in device layers.

Example fabric layers may include processor and/or memory devices which are fabricated on Silicon on insulator (SOI) substrates or bulk Silicon (Si) substrates. Additionally, each device layer may include at least one interconnect for interconnecting external circuits (referred to as chiplets).

Example fabric layers may also include quantum-well devices which are fabricated with high-mobility materials, such as fully depleted silicon-on-insulator (FD-SOI) materials (e.g., in quantum-well devices having a thickness between about twenty two nanometers (nm) and about twenty eight nm). Such quantum-well devices may be suitable for low-power applications including, for example, the Internet of Things (IoT). Example device layers may further include Nanowire FETs in some embodiments. In the backend, low-k treatments of nanowire FETs may be critical. Self-alignment of nanowire FETs may also be very important.

It is possible to operate some of the circuit elements or devices (e.g., transistors) in the fabric at low temperatures (e.g., a temperature which is room temperature down to about 4K and below) to provide for reduced operating voltages, higher speed operation and low power dissipation. Additionally, it is possible to utilize transistor technology with “low” and/or “ultra-low” power requirements and increased switching speeds in comparison to room temperature transistor devices in device layers. It is also possible to consider room temperature and/or high temperature devices as low temperature devices if these devices are able to operate at low temperature ranges. 2D materials (e.g., Graphene) and/or 2D material based devices (e.g., Vanadium dioxide based hybrid field effect transistors) may be used as a functional section or device layer, or be provided as part of a functional section or device layer. Various bandgap materials including silicon (Si), germanium (Ge), indium antimonide (InSb), indium arsenide (InAs), indium arsenide (InP), gallium phosphide (GaP), gallium arsenide (GaAs), gallium sulfide (Gas), cadmium sulfide (CdS), cadmium selenide (CdSe), cadmium telluride (CdTe), and zinc oxide (ZnO) may further be used to fabricate device layers.

As used herein, the term “chiplets” is used to describe an integrated circuit (IC) device containing a well defined subset of SoC (system-on-chip) functionality. These are tiny semiconductor chips with specialized functionality. The terms “chiplets” and “chips” may be used interchangeably.

As used herein, the term “interposer” in the wafer-scale fabric is used to describe an interconnect structure capable of electrically coupling two or more semiconductor structures together.

As used herein, the term “module” is used to describe an electrical component having a substrate (e.g., a silicon substrate or printed circuit board (PCB)) on which at least one active electronic device, such as a semiconductor device is disposed. The module may include a plurality of conductive leads adapted for coupling the module to electrical circuitry and/or electrical components located externally of the module. One known example of such a module is a Multi-Chip Module (MCM). These modules are available in a variety of shapes and forms. These may range from pre-packaged chips on a PCB (to mimic the package footprint of an existing chip package) to fully custom chip packages integrating many chips on a High Density Interconnection (HDI) substrate.

As used herein, the term “processor” is used to describe an electronic circuit that performs a function, an operation, or a sequence of operations. The function, operation, or sequence of operations may be hard coded into the electronic circuit or soft coded by way of instructions held in a memory device. A “processor” may perform the function, operation, or sequence of operations using digital values or using analog signals.

In some embodiments, the “processor” may be embodied, for example, in a specially programmed microprocessor, a digital signal processor (DSP), or an application specific integrated circuit (ASIC), which may be an analog ASIC or a digital ASIC. Additionally, in some embodiments the “processor” may be embodied in configurable hardware such as field programmable gate arrays (FPGAs) or programmable logic arrays (PLAs). In some embodiments, the “processor” may also be embodied in a microprocessor with associated program memory. Furthermore, in some embodiments, the “processor” may be embodied in a discrete electronic circuit, which may be an analog circuit or digital circuit.

As used herein, the term “through oxide via (TOV)” is used to describe a via (e.g., micro via) in a semiconductor structure used to connect adjacent device layers. The TOV passes through one or more oxide, dielectric, and/or metal layers and terminates at a predetermined Silicon (Si) layer or surface.

As used herein, the term “via first” may be used to describe a micro via and/or a submicro via used to make at least one electrical connection between a first device layer and second device layer in a semiconductor structure including at least two device layers. Additionally, as described here, the term “via first” may also be used to describe a micro via and/or a submicro via passing through a dielectric material or layer (in some embodiments, only the dielectric material or layer) to make at least one electrical connection between a first device layer and a second device layer in a semiconductor structure including at least two device layers. For a via first process, the first device layer and the second device layer are completed separately. As one example, a partial via material is added on first and/or second opposing surfaces (i.e., top and/or bottom surfaces) of the first second device layers and subsequent bonding and/or post bonding process create a via first between the first and second device layers.

The via first may be filled with at least one metal or alloy having a high Coefficient of Thermal Expansion (CTE) to produce a rigid, robust, and conductive via first joint between the at least two device layers during the composite bonding process. High temperatures and/or high pressures may be applied and used to bond the two device layers and provide a three-dimensional (3D) interconnection (i.e., interconnect) among the device layers. The high CTE metal or alloy are expanded at relatively high temperatures and interdiffuse with each other to produce the 3D interconnect. Alternatively, the via first may be filled with a low temperature fusible metal which melts and interdiffuse during bonding or post bonding processes.

As used herein, the term “via last” is used to describe a micro via and/or a submicro via used to make at least one electrical connection between a first device layer and a second device layer in a semiconductor structure including at least two device layers. Fabrication of the first device layer is completed first, and the second device layer is deposited over the first device layer. The second device layer is completed with via last process. A pad layer which includes one or more interconnect pads may be added after via last process. In one embodiment, the via last is filled. Additionally, in one embodiment, the via last can be unfilled or partially filled. Via last may pass through the device layers (e.g., second device layers) and, in some embodiments, one or more isolation layers or materials. A titanium (Ti) material having a thickness of about ten nanometers (nm) and, a metal organic chemical vapor deposition (MOCVD) Titanium Nitride (TiN) liner having a thickness of about five nm, and tungsten plugs may be used for via lasts. A MOCVD or chemical vapor deposition (CVD) TiNx, with X less than or equal to 1, is preferred for better conformal coating.

As used herein, the term “through silicon via” (TSV) is used to describe a vertical interconnect which passes substantially through one or more of a silicon wafer, a silicon die, a silicon interposer, silicon active circuits, silicon passive circuits, or other silicon circuits, components or layers. TSVs may be fabricated by different methods and approaches. In Silicon (Si) via-first approaches, for example, TSVs are fabricated prior to fabrication of active devices (i.e. bipolar or MOSFET devices) to which the TSVs may be coupled. The approach includes patterning the TSVs, lining the TSVs with a high temperature dielectric (thermal oxide or chemical vapor deposition), filling the TSVs with doped polysilicon and using chemical mechanical polishing (CMP) techniques to remove excess polysilicon from one or more surfaces of the TSVs. Si via-first approaches allow for the use of high temperature processes to insulate and fill the TSVs.

In Si via-middle approaches, TSVs are fabricated after forming the active devices to which the TSVs may be coupled, but before back end of line (BEOL) stack fabrication. The approach includes patterning the TSVs after a contact process, lining the TSVs with a low temperature dielectric deposition, and then filling the TSVs with single/multiple barrier metals. Typically the TSVs are filled with Copper (Cu) and/or tungsten (W). For TSVs filled with Cu, a Cu seed layer is disposed on top of a barrier layer and a subsequent Cu electroplating fills the TSVs. The TSVs are then planarized using CMP techniques. For W, chemical vapor depositing (CVD) processes are used to fill the TSVs, and CMP techniques are used to remove excess polysilicon from one or more surfaces of the TSV. W is preferred for filling high aspect ratio TSVs (e.g., TSVs with aspect ratio of height-to-width >10:1). In general, Cu is used to fill low aspect ratio TSVs (e.g., TSVs with aspect ratio <10:1). Si via-middle process are useful for fabricating TSVs with a small via pitch, TSVs having minimal blockage of wiring channels, and TSVs having a low via resistance, for example.

In front side Si via-last approaches, TSVs are fabricated at the end of the BEOL processing of the wafer. Si via-last approaches are similar to Si via middle approaches, but Si via-last approaches use low temperature dielectric depositions (<400 C) compared to higher temperature dielectric compositions (<600 C) in Si via middle approaches. Front side Si via-last approaches may be suitable for their coarse TSV feature size, which simplifies the process of integrating TSVs into semiconductor structures. The front side Si via-last approaches may also be useful for wafer-to-wafer bonding. In such approaches, TSVs can be formed at the end of the wafer-to-wafer bonding process, connecting multiple layers in the multi-layer (e.g., three-dimensional (3D)) stack of wafers or semiconductor structures.

Front side Si via-last approaches may use TSV etch as well as the entire BEOL dielectric stack. Backside Si via-last approaches also use wafer to wafer (or semiconductor structure to semiconductor structure) stacking. The wafers may be bonded together using oxide bonding or polymer adhesive bonding, either front-to-front or front-to-back. The wafers may be thinned by etching and or polishing. Additionally, a TSV may be formed in the wafers by etching a via down to bond pads on a top wafer and a bottom wafer. The process includes patterning the TSVs after the contact process, lining the TSVs with a low temperature dielectric deposition, and then filling the TSVs with a single/multiple barrier metal (e.g., Cu and/or W). The TSVs are then planarized through a subsequent CMP process.

A number of inorganic and organic dielectric materials having a thickness in a range of about one hundred nanometers (nm) to about one thousand nm may be used to insulate the TSVs. TSV dielectrics may be required to have good step coverage (at least 50% through the depth of the trench), good thickness uniformity (<3% variation across the wafer), high deposition rate (>100 nm/min), low stress (<200 MPa), low leakage current (<1 nA/cm2), and high breakdown voltage (>5 MV/cm). Plasma-enhanced chemical vapor deposition of SiO₂ or SiN, or sub-atmospheric chemical vapor depositions (SACVD) of SiO₂, are some examples of insulator deposition. The most commonly used conductors to fill TSVs are doped polysilicon, tungsten (W), or copper. W deposited by CVD has a good fill of the TSV and may be integrated with the contacts to which the TSVs are to be coupled. A TiN liner is required to ensure that the WF₆ precursor does not attack the Si substrate in the TSV. A disadvantage of W compared to Cu is that it has a high intrinsic stress (1400 MPa for W, 20 MPa for Cu).

Reactive-ion-etching (RIE) may be used to create high aspect ratio TSVs and deep trench structures in the Si (i.e., for capacitors or for isolation) in which the TSVs are provided. In one embodiment, a TSV RIE Bosch process may be used to fabricate the TSVs, with process alternating between deposition and etching steps to fabricate deep vias. SF₆ isotropic etching of Si may not be suitable for forming TSVs (which require a highly anisotropic etch). Fluorocarbon chemistry (e.g., C₄F₈) may be used for anisotropic etching achieved through the deposition of a chemically inert passivation on the sidewall of the TSVs.

Chemical mechanical polishing (CMP) may be used for planarization of metal filled vias (e.g., micro vias), for example. Additionally, a metal contact (i.e. pad) in an upper device layer (e.g., the second device layer) may be an annulus with about a one point five micrometer (μm) opening that also functions as a self-aligned mask (e.g., hard mask) during the plasma etch of the oxide beneath it to reach a corresponding metal contact in a lower device layer (e.g., the first device layer). In order to fully dispose and electrically connect the via, the size of the metal contacts, and thus the pitch of the vertical interconnect, is made proportional to about twice the wafer-wafer misalignment of the wafers including the first and second device layers.

As used herein, the term “bulk Complementary metal-oxide semiconductor (CMOS)) fabrication techniques” is used to describe semiconductor fabrication techniques in which CMOS circuit elements or devices are fabricated in a Silicon (Si) substrate.

As used herein, the term “Silicon-On-Insulator (SOI) CMOS fabrication techniques” is used to describe semiconductor fabrication techniques in which CMOS circuit elements or devices are isolated from a Si substrate by one or more dielectric materials. SOI CMOS fabrication techniques may be used to significantly reduce junction capacitances and allow the CMOS circuit elements or devices to operate at a “higher” speed or at a substantially “lower” power level at a same speed as those which are fabricated through bulk CMOS fabrication techniques, for example. SOI CMOS fabrication techniques also reduces or eliminates latch up effects that may be found in bulk CMOS, and improves the short channel effect and soft error immunity.

A Josephson junction (JJ) is defined as two superconductors having an allowed interacting through a so-called “weak link,” where the “weak link” may be provided from a thin insulating barrier, a normal metal, or a narrow superconducting constriction-respectively referred to as an S-I-S, S-N-S, or S-C-S junction. A supercurrent flows/tunnels through this weak link, even in the absence of a voltage. The critical current of the junction is related to the superconducting gap of the electrode materials as well as the type and thickness of the insulating barrier. It is often characterized by a critical current density Jc and the area A of the junction such that Ic=Jc×A.

Josephson tunnel junctions are formed by two superconducting electrodes separated by a very thin (˜1 nm) insulating barrier. In this configuration, the collective superconducting order of one electrode (parameterized by a phase φ₁) coherently connects with that of the other electrode (φ₂) via the elastic tunneling of Cooper pairs through the barrier. The resulting supercurrent, I, and junction voltage, V, are related to the superconducting phase difference, φ=φ₁−φ₂, across the junction.

As used here, the term “Superconductive single-flux-quantum (SFQ) integrated circuits” is used to describe a circuit which operates at a cryogenic temperature of about 4 K, is based on switching flux quanta in and out of superconducting loops containing Josephson junctions. Building circuits and logic gates exploiting SFQ operation involves combining loops and inductors for storing flux along with transformers and JJs for control and switching. In a simple SFQ circuit use, a superconducting ring is interrupted by a single Josephson junction, and a transformer couples an amount of magnetic flux into the ring proportional to an externally applied control current. If the control current results in the loop current IL exceeding I_{c}, then a short voltage pulse will result across the junction along with a 2*π phase shift. This corresponds to a single quantum of flux passing through the junction. The characteristic switching time is 1 ps and the switching energy is 10⁻¹⁹ J. Another example SFQ circuit is a D flip-flop which has a storage loop formed by the junctions J₁ and J₂, and the inductor L₂. With a bias current applied to keep J₁ close to its critical current, an input ‘D’ pulse entering through J₀ will switch J₁ and inject an SFQ pulse into the storage loop resulting in an increase in the circulating current Iₛ passing through J₂. Readout is performed with an incoming CLK pulse. In the presence of a stored pulse, Iₛ, an incoming CLK pulse will cause J₂ to switch resulting in an output pulse at ‘Q’. With no stored pulse, the CLK pulse is insufficient to switch J₂ and there will be no output pulse at ‘Q’. In one example, a niobium-based superconducting integrated-circuit fabrication process for superconducting circuits. It is based on a Nb/Al—AlOₓ/Nb Josephson junction trilayer with a J_{c} of 10 kA/cm². It utilizes 248-nm photolithography and planarization with chemical-mechanical polishing (CMP) for wiring-layer feature sizes down to 350 nm and Josephson junction diameters down to 500 nm. The process uses Nb superconducting layers, Mo-based resistance layers, and Nb-based superconducting interconnects between all metal layers. The process supports superconducting circuits with a single Josephson junction layer. Metal wiring layers are separated by the silica-based dielectric, and microvias are used to interconnect metal layers to form superconducting circuits.

As used here, the term “conductive structure” is used to describe metal/conductive layer(s)/Plane(s) and electrical connections (e.g. via, TSV, TIV, TOV) between metal layers for semiconductor or superconductor structures.

As used here, the term “integrated substrate” is used to describe a substrate for assembly of electronic components comprising conductive structures, active circuits that establish connectivity between said conductive structures and other active circuits where said integrated substrate is implemented so as to eliminate and/or minimize and/or reroute and/or reconfigure the substrate during fabrication and/or operation. The active circuits may be made with semiconductor-based devices (e.g. transistors) or superconductor-based devices (e.g. JJs). In one embodiment, integrated substrate may be a semiconductor structure and/or section.

An in-wafer reconfigurable logic fabric is disclosed that allows the development of advanced wafer-scale multi-chip systems suitable for AI and high-performance embedded computing. There are several benefits to this approach, including:
Flexible integration and data routing: the ability to create flexible adapter logic to interconnect chiplets with incompatible protocols.
Adaptive fault-tolerance: the ability to re-route failed or broken connectivity between chiplets.
Adaptive computing platform: the ability to move computation closer to the memory, by instantiating the computation function in the reconfigurable logic inside the wafer physically located next to the memory where the data is stored. This “computational mobility” could lead to tremendous performance efficiency by moving the computation closer to the memory and thereby eliminating long-distance, high-latency processor-to-memory communications.

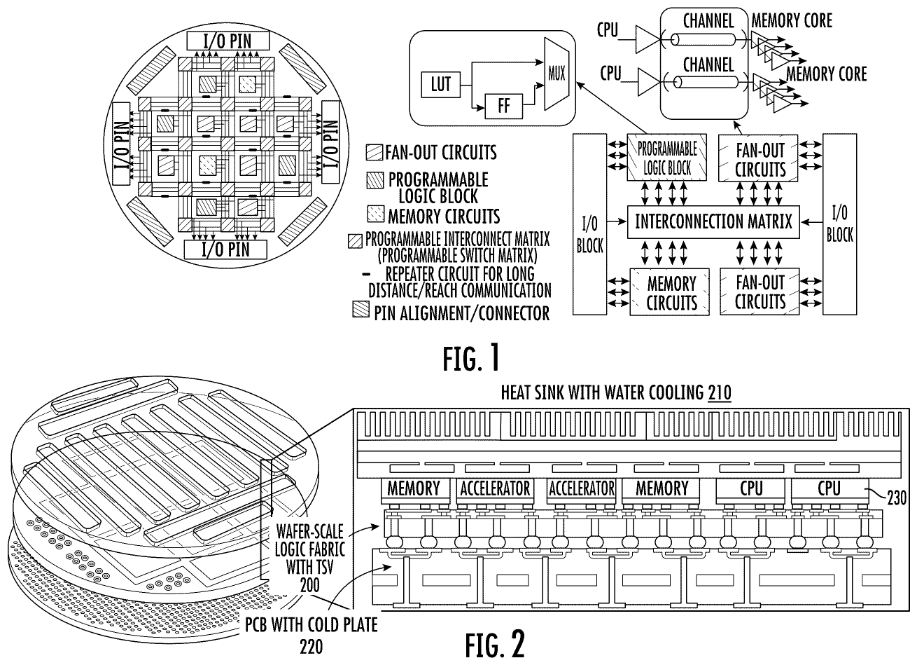

A fully functional reconfigurable wafer-scale logic fabric for high performance computing is described. The key features of this fabric that differentiate it from current technologies are as follows:
1. A testable wafer-scale logic fabric including active and passive layers. FIG. 1 and the accompanying text describe these layers in more detail. Such a wafer is designed to simultaneously provide the mechanical substrate for multi-chip module integration and the electrically-active reconfigurable interconnect fabric.
2. An under-bump metal (UBM) layer, which is a solder compatible surface used for 2-D and 3-D integrations, that enable the placement and connection of chips to the wafer.
3. Single or multiple passive routing layers between testable wafer-scale logic fabric and under bump metal (UBM) layer. Passive routing layers can be re-routed to eliminate defects in logic fabric identified during testing to create fully functional wafer-scale logic fabric prior to chiplet integration. This passive routing is based on a maskless approach that will modify the routing layer to reroute communications around defect(s) so that they are removed from the instantiation of the system.
4. Configurable routing circuits (e.g. switches) that are used to implement the reconfiguration and/or repair of the routing. These are implemented with active device layers in the wafer-scale fabric and/or integrated routing resource chiplets.
5. Routing layer(s) will thus be specific to individual wafers while meeting the same higher-level specification. Physical design of the routing layer as configured will primarily depend upon room-temperature wafer-scale testing of said individual wafer.

The present disclosure also describes packaging and thermal solution suitable for reliable 2D-3D integrated reconfigurable wafer-scale logic fabric.

First, an overview of the platform is presented. The graphic on the left side of FIG. 1 shows a wafer-scale reconfigurable logic fabric and integration substrate schematic. Note that this wafer is designed to simultaneously provide the mechanical substrate for multi-chip module integration and the electrically-active reconfigurable interconnect fabric. Specifically, the wafer may include programmable logic circuits, memory circuits, fan out circuits, as well as the programmable switch matrix. Additionally, the configuration of these circuits is variable, and may be adapted based on the overall functionality.

The components on the right side of FIG. 1 show a selected area of wafer-scale platform where IP blocks on a wafer may be connected by advanced wafer-scale routing using the re-configurable interconnection bus to move data over a wide parallel connection. The figure also shows that the programmable logic circuit may be comprised of look up table (LUTs) and flip-flops, although other configurations, such as gate arrays, are also possible. Additionally, the fan out circuits allow a signal to be replicated and distributed through the wafer as necessary. While memories, fan out circuits, and programmable logic are used, it is understood that the circuitry on the wafer may also include power supplies, clock generators, output amplifiers, and/or voltage regulators.

Input and output (IO) are critical for computation. This figure shows a selective area wafer-scale memory block (which may be a cache). In some embodiments, the wafer is configured such that a CPU chiplet is disposed on top of this memory. By bringing the memory underneath the CPU chips, interconnect delay and communication overhead may be reduced, while data rate is increased. According to Moore's law, transistor densities roughly double every 2 years, but the rate of improvement of IO data rates has only been a doubling every 4 years. The effort to develop 5-10 um pitch micro-bump-based interconnects will reduce this delta significantly.

As noted above, the CPU, GPU, FPGA, accelerator, memory chips and other devices may be mounted on the wafer. Throughout this disclosure, these devices may be referred to as chiplets. These chiplets may be mounted to the wafer using industry standard ball-grid arrays (BGAs). In some embodiments, flip chip techniques are used to attach the chiplets to the wafer. More details about the connection of chiplets to the wafer may be found in PCT/US23/14893, the disclosure of which is incorporated by reference in its entirety. However, for better signal continuity between the chips and wafer, BGAs may be replaced with anisotropic conductive film (ACF) to create electrical connection and minimize CTE mismatch between the chips and silicon wafer. It is possible to use gold particle filled silicone as flexible and stretchable ACF.

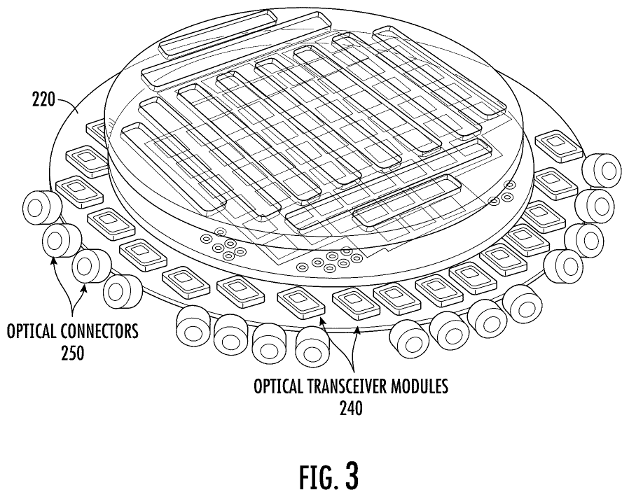

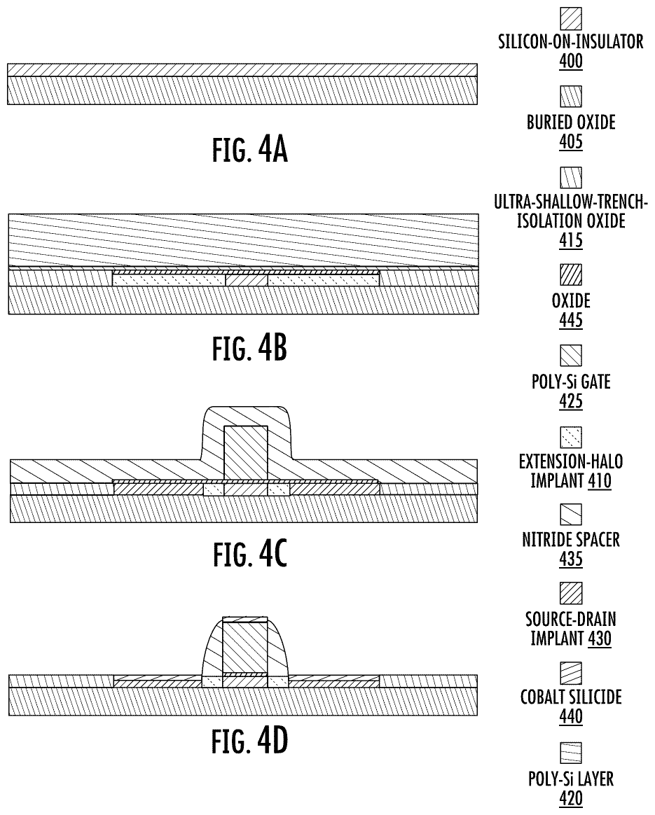

FIG. 2 presents a side view diagram of a package that includes the wafer-scale re-configurable logic fabric 200 based computing architecture, showing fully integrated wafer-scale platform to accommodate tens of processors chips (also known as integrated circuits). A wafer-scale re-configurable logic fabric 200 with finer pitch, high-bandwidth dense connections with minimum chip-to-chip spacing allows better heat dissipation. Furthermore, the heat sink 210, micro-channel, impingement cooling, micro-jet cooling and PCB 220 (which form a base circuitized substrate) with embedded cooling improves heat dissipation. The figure shows multiple chiplets 230, which may be bare die processor/memory/accelerator chips, attached to the wafer-scale re-configurable logic fabric 200 and interconnected through the wafer. Each of the chiplets 230 are mounted onto the wafer through a ball-grid array and/or micro-bumps and/or micro pillar and/or hybrid metal based interconnect, and each of the array connections connect to some reconfigurable logic that enables signal/protocol transformations and computing operations. From there, connections may be made to other parts of the wafer through the wafer-scale reconfigurable logic fabric 200. In this case, the diagram shows connections to a neighboring chiplet, which also is mounted on the wafer via micro-bumps and/or solder coated micro-bumps or micro-pillars with solder tip. Solder melt temperature generally dictates flip-chip bonding temperature. For example, tin-lead or tin-gold solder generally use melt temperatures that are at or above solder melt temperature for interconnecting chips to wafer-scale fabric. For soft solder, such as Indium, lower bonding temperature (below solder melt temperature) can be used for interconnecting chips to wafer-scale reconfigurable logic fabric 200. All the interconnects between the chiplets 230 are through wafer-scale routing, and the interconnects between chiplets on the wafer-scale reconfigurable logic fabric 200 may be as small as wiring within a chiplet. Wafer-scale through-via (such as, for example, through Silicon via) will route the signal out to the PCB 220 for cables and connectors as depicted in FIG. 3 of the wafer-scale assembly. Specifically, FIG. 3 shows a PCB 220 with optical transceiver modules 240 in communication with optical connectors 250. In general, a ball-grid array (BGA) is used to connect the PCB 220 to the wafer-scale reconfigurable logic fabric 200. It is preferred to use different solder melt temperature for the BGA than micro-bumps. For example, eutectic tin-lead (SnPb) solder may be used to connect chiplets to the wafer-scale reconfigurable logic fabric 200 and tin-silver-copper (SAC305) BGA may be used to connect wafer-scale reconfigurable logic fabric 200 to the PCB 220. Eutectic tin-lead (SnPb) solder melts at a lower temperature than SAC305. This will allow the chiplets 230 to be reworked (removed and replaced or rebonded chips) without melting SAC305 BGA solder. Thus SAC305 BGA solder, which interconnects the PCB 220 to the wafer-scale reconfigurable logic fabric 200, will be stable during chiplet rework. In one example, the BGA may be replaced with anisotropic conductive film (ACF) to create electrical connection and minimize CTE mismatch between Si wafer and PCB 220. It is possible to use gold particle filled silicone as a flexible and stretchable ACF. In one example, the wafer-scale reconfigurable logic fabric 200 may have transistors and/or junctions and/or photonic circuits integrated and/or fabricated side-by-side to provide an interface that facilitates dynamic reconfiguration of the communication topology.

A strategy to use lithography (I-line and EX4) has been developed to fabricate 200 mm wafer-scale fabric-based substrates for multi-chip modules (MCM) for interconnecting multiple chips (CPU, GPU, memory, etc.) for next-generation computing systems. In the example embodiment described herein, I-line, EX4 and laser direct write are used in conjunction because each lithography tool occupies a different place in the trade space between field size, feature size, throughput and cost. By decomposing the fabrication process in a way that employs multiple lithography tools, the benefits of each may be exploited as needed for different steps of the process. The packaging strategy includes the development of MCM (50 mm×50 mm) using large single I-line reticles, followed by reticle stitching to fabricate nearly the largest possible stitched reticle based MCM (100 mm×100 mm) using a four mask/layer process. The stitching process starts with sequential exposure of multiple I-line photomasks—with small overlap (stitched area)—to realize larger combined circuit areas for design-critical MCM layers with minimum linewidths of 0.8-1 μm. The process also utilizes laser direct write (LDW)/wafer-scale lithography to make wider (>1 μm) features such as fan-out circuits, extending the stitched circuit area to include the entire 200 mm wafer as a single wafer-scale MCM platform.

The wafer-scale platform is used to couple multiple chiplets to demonstrate a heterogeneous-integration approach for a possible hybrid computing system. This disclosure describes a system to create a heterogeneous integration approach for chiplet-to-wafer-attachment process using microbump technology. It is further possible to use a hybrid (e.g. via first, via last) approach and/or direct metal-to-metal bonding for 2D, 2.5D and 3D integration. For this integration, a mix-and-match interconnect scheme is being defined that performs three functions:
(1) provides a versatile integration approach to any chip technology;
(2) is able to convert any chip to flip-chip; and
(3) interconnect solution for multilevel provides an assembly.

This approach for system integration provides yield improvement and reworkability. The current fabrication processes may be used to fabricate a wide range of die-to-die and die-to-wafer level integrations using various microbump technologies. Overall, the results suggest that the heterogeneous integration approach comprising wafer-scale MCM and microbump technology enable the design and realization of larger-scale computing platform.

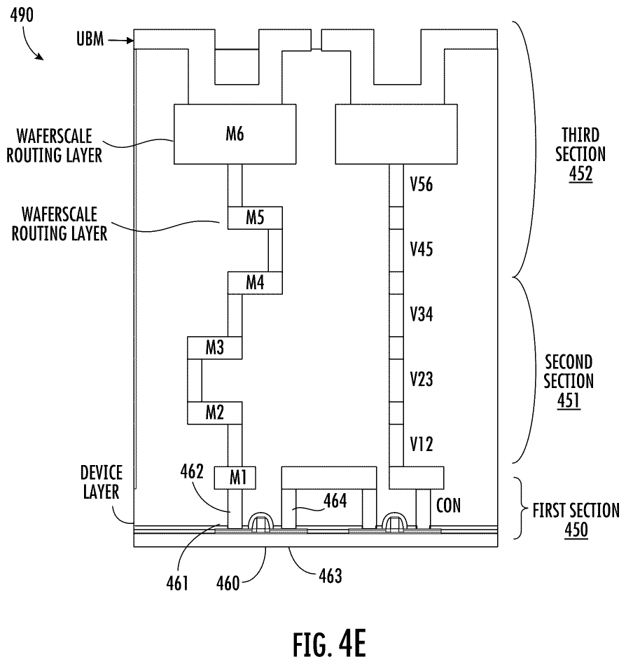

The following describes this platform in more detail. FIGS. 4A-4D shows a sequence used to create the underlying circuitry on the wafer. The sequence starts, as shown in FIG. 4A, with a silicon layer 400 disposed on a buried oxide layer 405. Then, as shown in FIG. 4B, various implants are performed on the silicon layer 400. Specifically, an extension halo implant 410 is performed on either side of the regions which will become the gate. Further, an ultra-shallow implant is performed to create shallow trench isolation (STI) 415 between adjacent devices. Additionally, a poly-silicon layer 420 is then deposited or grown on top of the silicon layer 400 after implantation. As shown in FIG. 4C, the poly-silicon layer 420 is then etched to remove material, except above the gate region, to form the poly-silicon gate 425. Next, a dopant implant is performed to create the source and drain contacts 430. After the implants are performed, a nitride layer 435 is deposited on top of the silicon layer 400 and the poly-silicon gate 425. Finally, in FIG. 4D, the nitride layer 435 is removed, such as by etching, except in the regions on either side of the poly-silicon gate 425. Contacts are then created for the gate, source and drain. These contacts may be cobalt silicide 440. A thin oxide 445 may be deposited prior to the poly-silicon layer 420 in the area beneath poly-silicon gate 425. This thin oxide 445 is known as gate oxide.

In one example embodiment shown in FIG. 4A-4D, the plurality of circuit fabrication steps are provided as three terminal devices (e.g., a field-effect transistors (FETs)). In one embodiment, layers are produced by fabricating individual semiconductor functional sections of fully depleted SOI (FDSOI) circuits, with a 150-nm to 20-nm FET gate length, 40-nm or less thick SOI (Silicon-On-Insulator) active layer, and multiple metal interconnect layers. The FDSOI circuits may, for example, be designed using conventional logic design rules. Although a FDSOI (Fully Depleted Silicon-On-Insulator) type of semiconductor technology that uses a thin layer of silicon on an insulating substrate is shown in these figures to create transistors, any other traditional bulk CMOS (Complementary Metal-Oxide-Semiconductor) technology may be used as well.

Additional aspects of the concepts, systems, circuits and techniques sought to be protected herein, with particular emphasis on semiconductor interconnect structures (e.g., via for metal joining layers) are described in conjunction with the figures below.

Referring now to FIG. 4E, an example of multi-layer semiconductor structure is shown. The semiconductor structure 490 includes multiple metal layers M1, M2, M3, M4, M5, M6, UBM, and a device layer (and a plurality of circuit components). A plurality of electrical connections, such as vias V12, V23, V34, V45, V56 are used for electrically coupling the circuit components to one or more of the plurality of conductive planes (such as a ground plane or a voltage plane). In the example embodiment shown, the plurality of circuit components are provided as three terminal devices (e.g., a field-effect transistors (FETs). Additionally, the plurality of electrical connections are provided from one or more electrical connections or vias using through hole vias, blind vias, buried vias, open vias, stacked vias, and step (or staggered) vias.

This multi-layer structure creates a plurality of vertically stacked sections. These vertically stacked sections may include semiconductor layers. In other embodiments, some or all of the vertically stacked sections do not include a semiconductor layer. The first section 450 includes one or more active layers. These active layers may include semiconductor devices, such as three terminal devices, similar to those shown in FIG. 4D. As shown in FIG. 4E, a first three terminal device 460 has a first terminal 461, also referred to as a source terminal, electrically coupled to conductive plane M1 via electrical connection 462 (which may be micro-via and or sub-micro via), a second terminal also referred to as a gate terminal (see FIG. 4D) and a third terminal 463, also referred to as a drain terminal, electrically coupled to the first of the plurality of conductive planes (M1) via an electrical connection 464 (e.g., contact micro-via and or sub-micro via). The second section 451 is disposed above the first section 450 and comprises multiple metal layers, including a second metal layer (M2) electrically coupled to a third metal layer (M3) via a plurality of electrical connections (V23), a fourth metal layer (M4) electrically coupled to conductive plane M3 via electrical connection V34. A third section 452 is disposed on top of the second section 451. In one example, the third section 452 comprises multiple metal layers and includes a fifth metal layer (M5) electrically coupled to a sixth metal layer (M6) using micro via and/or sub-micro via electrical connections (V56), an under bump metal (UBM), and the sixth metal layer (M6) electrically coupled to conductive plane UBM via electrical connection M6-UBM (not shown). In one embodiment, the device layer, M1 and M2 layers are used for reconfigurable wafer-scale routing layers. In another embodiment, the M5 and/or M6 metal layers are used for a repairable wafer-scale routing layers. It is further possible to use the M3 and/or M4 layers for a repairable wafer-scale routing layers. In one embodiment, adaptive reconfiguration may include one or more repairable wafer-scale routing layer(s).

In another embodiment, M3 and/or M4 metal layers are used a repairable wafer-scale routing layers. In one example, FIG. 4E is produced by sequentially fabricating individual semiconductor functional sections of fully depleted SOI (FDSOI) circuits, with a 150-nm to 2-nm gate length, 80-nm or less thick SOI active layer, and multiple metal interconnect layers. The FDSOI circuits may, for example, be designed using conventional logic design rules.

In one example, it is further possible that UBM-M6-V56-M5-V45-M4 creates the second section and the device layer-contact via-M1-V12-M2-V23-M3 creates the first section. The second section uses via V34 for interconnection with the first section. The second section may have single or multiple repairable routing layer(s) and first section or combination of first and second sections may have layers for reconfiguration.

It is further possible that the semiconductor structure in FIG. 4E may have multiple device layers fabricated sequentially or using wafer-level 3D integration (via last and/or via first approach) where each device layer is interconnected with each other by through oxide via (TOV) and/or through insulator via (TIV) and/or through Silicon via (TSV).

FIG. 4F is an example of a multi-layer semiconductor and/or superconductor structure. This structure comprises multiple metal layers L0, M0, M1, M2, M3, M4, M5, M6, M7, M8 (referred to as UBM or gold pad) and device layers (M5, J5, R5, C5 and M6) which define a plurality of circuit components. A plurality of electrical connections, such as vias I0, I1, I2, I3, I4, I5, I6, I7, C5, are used for electrically coupling the circuit components to one or more of the plurality of conductive planes (e.g., a ground plane or a voltage plane). In the example embodiment shown, the plurality of circuit components are provided as first and second electrodes of junction devices (such as, for example, Josephson Junctions (JJs)). Additionally, the plurality of electrical connections are provided from one or more electrical connections which may be through hole vias, blind vias, buried vias, open vias, stacked vias, and step (or staggered) vias. In one example, metal layers including L0, M0, M1, M2, M3, M4 may be the first section, device layers including M5, J5, R5, C5 and M6 may be the second section, and metal layers including M7 and M8 may be the third section. In another example, device layers including M5, J5, R5, C5 and M6 may be reconfigurable section. Furthermore, metal layers M6 and M7 may be lithographically repairable (e.g., adaptive reconfigurable) layers.

In one embodiment, FIG. 4F is an advanced process for superconductor electronics that uses 8 superconducting metal (Nb) layers for circuit interconnects: M0, M1, M2, M3, M4, M5, M6, and M7, high kinetic inductor layer (HKIL) L0, milliohm resistor R4, and high sheet resistor R5. The metal layers are separated by SiO₂ interlayer dielectric (ILD). ILD is deposited by PECVD and planarized by CMP to achieve global and local planarity. The target ILD thickness between metal layers after CMP is 200 nm. Contacts between metal layers are made by etching contact holes in the corresponding ILD and filling them with the next metal layer. As an example, patterning/etching of I0 ILD layer on top of M0 metal creates contact holes that are filled by the next metal layer M1, forming I0 vias (M0-M1 contact). There are also C0, I0, I1, I2, I3, I4, I5, C5, and I6 vias. One active JJ (Josephson junction) device layer (J5) is used. The M5 layer may have Nb and a thin Al layer where Al layer and fraction of Nb layer oxidized and/or anodized to create a Nb—Al-oxide layer. The oxide layer create “weak link,” where the “weak link” may be provided from a thin insulating barrier of the JJ. M5 with Nb—Al-oxide and J5 electrode create JJ. In one example, JJ is used M5-Aluminum oxide and J5. Contact to this layer is made by both planarization of ILD A5 and etching contact holes C5 in ILD layer A6. In one embodiment, Ix and Cx (e.g., X=0, 1, . . . ) represents two different via within same oxide layer. In general, Ix vias are larger diameter and longer/taller than Cx vias.

In one embodiment, device layer, J5 and M4 layers are used for reconfigurable wafer-scale routing layers. In another embodiment, M6 and/or M7 layers are used as repairable wafer-scale routing layers. In one example, FIG. 4F represents a superconducting structure such as single flux quantum (SFQ), adiabatic quantum-flux-parametron (AQFP), quantum flux parametron (QFP) or others.

In these embodiment, the active layers may be superconductor layers that include the Josephson junction device layers.

Of course, other processes may be used to create the circuitry for the wafer. In some embodiments, at least one of 193 nm, 248 nm, and/or I-line lithography is used for the active circuits. In certain embodiments, at least one of 193 nm, 248 nm, I-line, 1-X or maskless lithography is used for the fan out, redistribution layer and interconnect circuits (see FIG. 1). In one example, the fan out, redistribution layer and interconnect circuits may be used for the repairable routing layer. In another example, adaptive reconfiguration may include repairable routing layer.

After the circuitry is fabricated, which is referred to as the front end of line (FEOL) fabrication, the routing layers need to be added. This may be done by alternating layers of an insulating material, such as silicon dioxide, and a conducting material, such as copper or aluminum or niobium.

In one particular embodiment, the wafer is fabricated using Deep UV EX4 reticles (22 mm×22 mm) to make individual building blocks, interconnected by four EX4 reticles with larger field i-line reticles (44 mm×44 mm), followed by i-line reticle stitching to fabricate stitched reticle of 88 mm×88 mm (7, 744 mm²). A high-resolution DUV stepper (Canon EX4 reticles) may be used for the junction layer and a large-field i-line (365 nm) stepper for the interconnection and stitching. This embodiment describes an interconnection scheme for 16 high-resolution DUV stepper (Canon EX4) reticles (7,744 mm²) without stitching at individual EX4 reticles, instead of stitching with a large-field i-line reticle as a method to significantly reduce the number of fabrication steps and improve yield. In one example, the EX4 reticle is used to fabricate the active layers (first section) such as transistors or JJs and associated fine line circuits; larger I-line reticles used for interconnecting individual active device layer reticles in the second section and stitching I-line reticles to connect all the active device layers to complete system or sub-system in the third section. It is further possible to use LDW or contact lithography to interconnect stitched reticle in a fourth section. In one example, LDW or contact lithography use entire wafer real state for device circuitization.

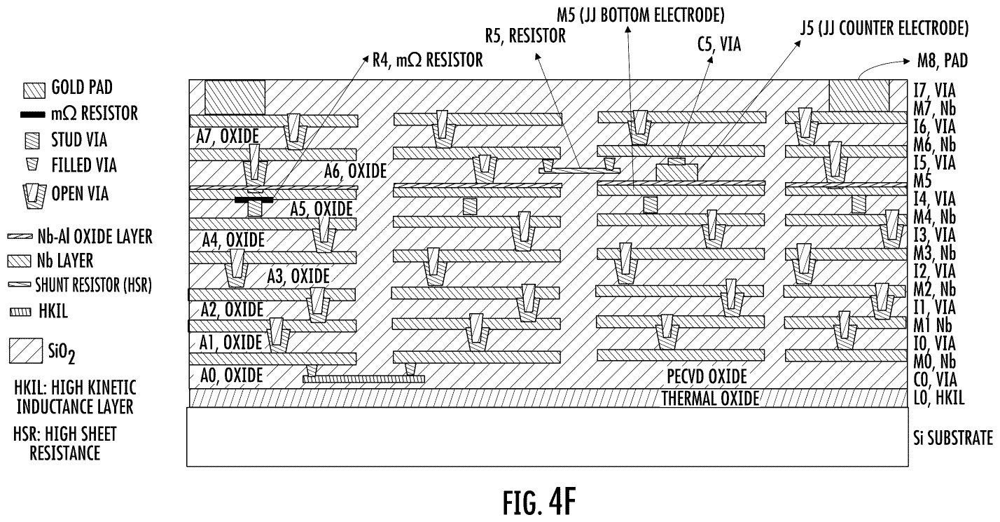

The cross-section in FIG. 5 has five (M4-M8) metal layers, one junction layer (J5), and one resistor layer (C5R) interconnected using niobium (Nb) vias (I4, I5, I5, I6, I7, C5J). Sixteen EX4 reticles, each of which was 22×22 mm², were interconnected to a large (88 mm×88 mm) structure. All the layers below M6 used DUV masks. All vias are created, including 15, C5J, and C5R, using DUV reticles, which is critical for maintaining the feature sizes associated with the DUV features on adjacent layers without requiring substantially larger via surrounds, which would have implications for circuit density and impedances. I-line Circuits on M6 primarily use impedance-controlled lines to connect individual EX4 features. Nb vias were used for both DUV and I-line reticles for interconnection. Wafer-scale routing for M7 primarily use impedance-controlled lines to connect individual I-line reticles. It is further possible to use laser direct write Wafer-scale maskless M7 routing layer capable of repairing M6 or below testable defects. Nb vias were used for both DUV and I-line reticles for interconnection.

The circuit has bump metal pads, labelled under bump metal (UBM) which are comprised of 20 nm Ti (adhesion layer), 50 nm Pt (barrier layer), and 150 nm Au, for flip-chip integration.

While the previous description discloses one particular embodiment, other embodiments are also possible. For example, as described above, in some embodiments, the device layers are formed within a reticle, which covers only a portion of the wafer. In other embodiments, different reticles form same/different devices, which are each less than the entirety of the wafer, may be used to interconnect to create larger interconnected device layers. In another embodiment, a device/stitched device layer that is the same size as the wafer may be used.

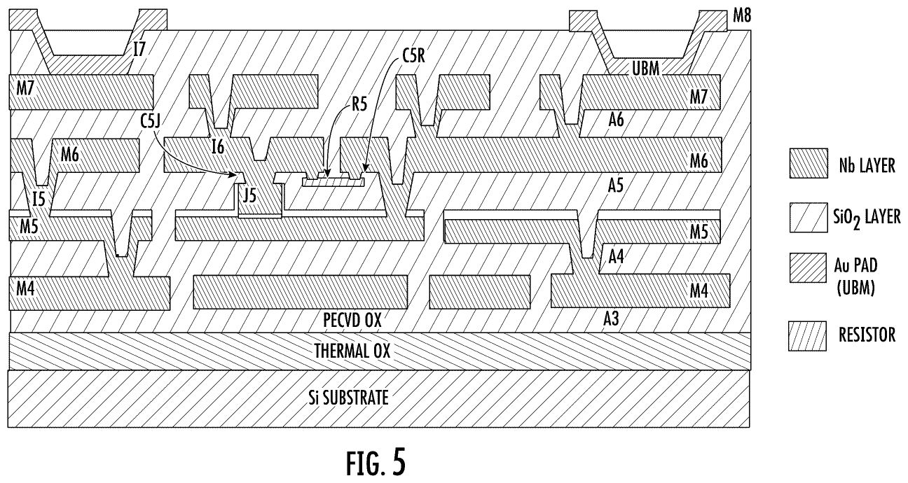

FIG. 5 shows an embodiment where there are no defects. However, advantageously, the present system is designed so as to accommodate defects. FIG. 6 shows a defect between M6 and M7 where a via has not been formed. Because of this defect, the under bump metal (UBM) layer directly above is not connected to M6.

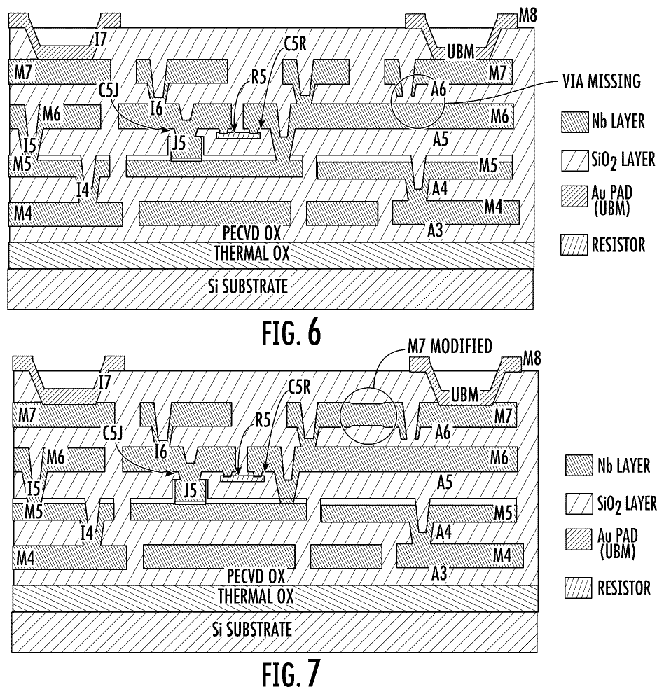

Importantly, electrical and/or optical testing may be performed after each metal layer is applied to validate that all connections have been correctly made. In this scenario shown in FIG. 6, testing will detect the missing via. In response, the mask for M7 may be modified. Specifically, as shown in FIG. 7, the M7 layer is changed (e.g. digitally changed) to form a different connection to the stub attached to the UBM layer.

Note that in some embodiments, the circuitry contained in the device layers of the wafer is redundant, such that defects detected in the metal layers may be corrected by utilizing a redundant circuit. In other embodiments, the functionality of the device may be degraded due to the defect. For example, one or more of the chiplets that are to be attached may no longer operate correctly.

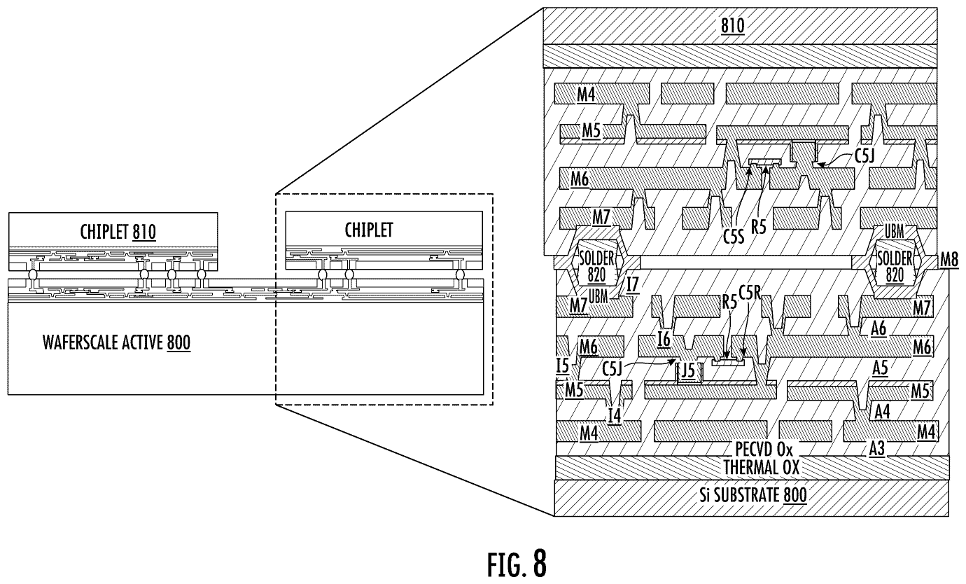

FIG. 8 shows a cross sectional view of the wafer 800 and a chiplet 810. The chiplet 810 is attached using flip chip techniques. A solder ball (M8) 820 is used to electrically connect the UBM layer (M7) of the wafer 800 to the UBM layer of the chiplet 810.

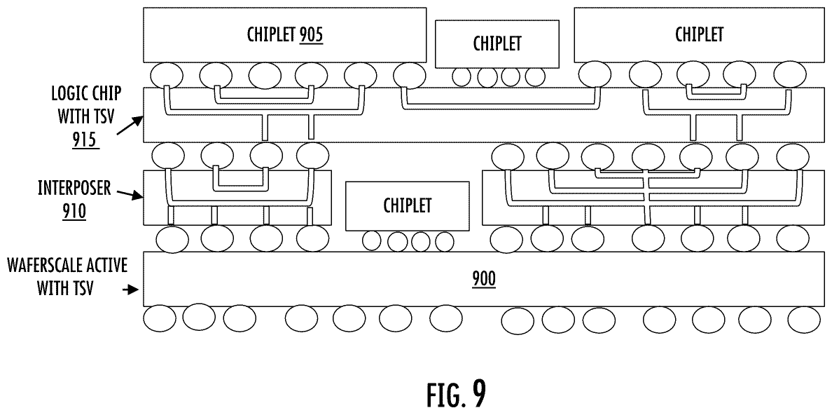

FIG. 9 shows a completed assembly, including the wafer 900, a plurality of chiplets 905, interposers 910, and logic chips 915. As used herein, the term “interposer” is used to describe an interconnect structure capable of electrically coupling two or more semiconductor or superconductor structures together. This may be a structure that includes a plurality of internal or external traces that are used to connect adjacent semiconductor structures, or semiconductor structures that are on opposite sides of the interposer. The logic chip 915 shown in FIG. 9 may be an interposer with some integrated circuitry. In some embodiments, the wafer 900 may include through silicon vias (TSVs) and/or through oxide via (TOV) and/or through insulator via (TIV). In this way, chiplets 905 or printed circuit boards may be disposed on both sides of the wafer. When chiplets 905 are disposed on opposite sides of the wafer 900, these chiplets 905 may be separated by a distance in the range of a few micron, a few tens of micron to a few hundreds of micron.

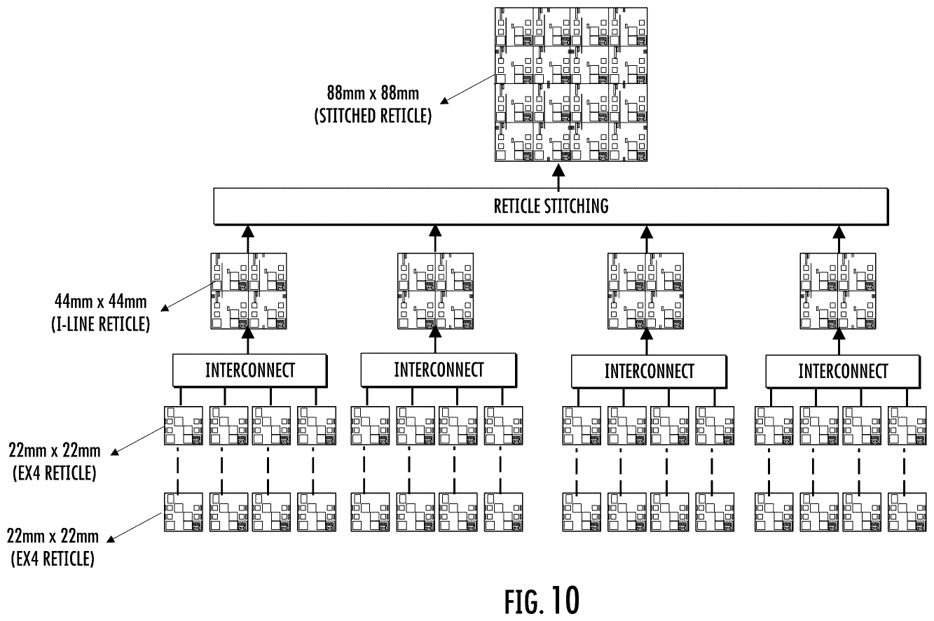

FIG. 10 describes a novel fabrication approach to interconnect 16 high-resolution deep UV (DUV EX4, 248 nm lithography) full reticle circuits to fabricate an intermediate large (88 mm×88 mm) area integrated circuit that can be interconnected with wafer-scale fabric. The fabrication process starts by interconnecting four high-resolution DUV EX4 (22 mm×22 mm) full reticles using a single large-field (44 mm×44 mm) I-line (365 nm lithography) reticle. This is followed by I-line reticle stitching at the boundaries of 44 mm×44 mm fields to fabricate large (88 mm×88 mm) area integrated circuit. Considering that no stitching requirement for high-resolution EX4 DUV reticles is employed, the present fabrication process has the potential to advance the scaling of superconducting and semiconducting devices.

In one embodiment, FIG. 10 represents an AI based fabrication process starting from individual EX4 DUV reticle based circuits and their interconnection schemes (decision tree) to fabricate a large (88 mm×88 mm) area integrated circuit. As a first step, multiple EX4 DUV reticles are vertically interconnected to achieve smallest EX4 lithographical feature (e.g., 250 nm) in the circuit. As a next step, four EX4 DUV reticle-based circuit layers (22 mm×22 mm) are interconnected with an I-line reticle-based circuit layer (44 mm×44 mm) using sub-micron EX4 DUV vias. I line reticles (44 mm×44 mm) are then connected via stitching, ultimately allowing full connectivity of the 16 EX4 DUV reticles through the I-line circuit layer. EX4 and I-line reticle interconnection and I-line reticle stitching can use one or more metal layers. In one example, an EX4 reticle is vertically interconnected to another EX4 reticle in the first section, an EX4 reticle is vertically interconnected to an I-line reticle in the second section, and an I-line reticle stitched to another I-line reticle in the third section.

In another embodiment, FIG. 10 further describes the design schemes for fabricating a large (88 mm×88 mm) area integrated circuit that can be interconnected with wafer-scale fabric. FIG. 10 illustrates a decision tree optimized process flow and defines how many photomasks are needed for making a given N-metal layer system. In one example, the fabrication scheme (for example, the cross-section shown in FIG. 5) uses a 200 mm wafer fabrication process comprising 13 photomasks. Eight (tiled) EX4 DUV photomasks with a 22 mm×22 mm field size were used to create junctions, resistors, interconnects, etc. Four (tiled) I-line photomasks with a field size of 44 mm×44 mm were used to interconnect the DUV reticles and reticle stitching for each set of four 22 mm×22 mm circuits. Finally, a final photomask is used to provide the circuit wiring on individual I-line reticles with a field size of 44 mm×44 mm so as to stitch/join together at a stitch boundary to create a large field of 88 mm×88 mm.

In another example, an AI driven approach for wafer-scale fabric results in productive use of wafer real estate and may be achieved without sacrificing the critical dimensions by combining EX4, I-line and laser direct write (LDW) mask-less method. For example, FIG. 10 shows an interconnection of 16 high-resolution deep UV (DUV EX4, 248 nm lithography) reticles to create an 88 mm×88 mm large stitched reticle. Subsequently, laser direct write lithography (LDW) may be used for connecting stitched reticle with wider (>1 μm) lines, adding fan-out circuits and extending circuit features to the entire wafer real estate.

Thus, in summary, the present disclosure describes a wafer. The wafer includes an active transistor layer that includes circuitry. In some embodiments, the active transistor layer is created using reticles that are smaller than the entirety of the wafer. In certain embodiments, the reticles may be stitched together. In other embodiments, the mask is the same size of the wafer. The circuitry may include fan out circuits, memory cells, programmable logic, power supplies, clock generators, voltage regulators, amplifiers or other functions. The programmable logic may include lookup tables, flip flops, or a gate array.

Additionally, the wafer includes a reconfigurable fabric. This reconfigurable fabric may comprise a plurality of metal layers that are disposed on top of the active transistor and/or junction and/or photonic layer that allow the connections to be altered, based on defect testing. There may be 4 or more metal layers that are used for wafer scale routing. All of these metal layers may be configured according to test results.

The top metal layer may be an under bump metal (UBM) layer, suitable for attachment to balls, bumps, pillars, and other chiplets.

Thus, in one embodiment, the wafer, which includes the reconfigurable fabric and the active transistor layer, includes a plurality of connection points on its top surface. These connection points may be used to connect to chiplets, interposers or logic chips, as shown in FIG. 9, using microbumps.

The developed approach may, for example, be used to combine trusted and commercial foundry chips to create highly secured systems in which the commercial foundry chips provide desired circuit density/performance while the trusted foundry chips add system security. The potential for mix-and-match IC schemes will serve as a key advantage that will provide yield enhancements as well as power and performance benefits to many AI and/or signal/image processing systems.

The present system has many advantages. The approach differs from other technology platforms in many ways, including:
Simplified active device and interconnect process integrated into substrate to provide reconfigurable fabric
Isolation of active devices, interconnects, power and clock resources, etc. on the substrate from hybridized devices to allow for composable design
High-speed switch matrix routing that can be mapped and re-mapped as part of a high-level multi-chip design flow
Integration of configurable clock and power distribution resources
Integration of subcomponent bump bonding sites into both the fabric design and associated fabric models used in wafer-level circuit implementation

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A multi-layer wafer-scale fabric, comprising:
two or more vertically disposed sections, each of the sections having first and second opposing surfaces and including:
at least one insulating layer; and
a plurality of electrical connections extending between the first and second opposing surfaces;
wherein a first section comprises one or more active layers; and
wherein at least one of the two or more sections includes one or more repairable routing layers.

2. The multi-layer wafer-scale fabric of claim 1, wherein the one or more active layers comprise semiconductor layers.

3. The multi-layer wafer-scale fabric of claim 1, wherein the one or more active layers comprise superconductor layers.

4. The multi-layer wafer-scale fabric of claim 1, wherein a first active layer comprises at least one transistor layer provided as a reconfigurable logic fabric and/or dynamically reconfigurable logic fabric.

5. The multi-layer wafer-scale fabric of claim 4, wherein the reconfigurable logic fabric further comprises at least one of power supplies, clock generators, output amplifiers, voltage regulators, resonators, waveguides, and photonic circuits.

6. The multi-layer wafer-scale fabric of claim 1, wherein at least one section comprises under bump metal (UBM) provided as a through oxide via (TOV) structure or a through insulator via (TIV) structure.

7. The multi-layer wafer-scale fabric of claim 1, wherein the one or more active layers comprise a gate array and/or look up tables and/or D flip flops and/or a reconfigurable interconnect.

8. The multi-layer wafer-scale fabric of claim 1, wherein at least one through via or a through silicon via (TSV) is provided as an electrical connection between the sections.

9. The multi-layer wafer-scale fabric of claim 1, wherein the one or more active layers comprise at least one junction layer provided as reconfigurable superconducting logic fabric and/or dynamically reconfigurable logic fabric.

10. The multi-layer wafer-scale fabric of claim 9, wherein the superconducting logic fabric comprises at least one of single flux quantum (SFQ), adiabatic quantum-flux-parametron (AQFP), quantum flux parametron (QFP), power supplies, clock generators, output amplifiers, voltage regulators, resonators, waveguides, or photonic circuits.

11. The multi-layer wafer-scale fabric of claim 1, wherein a size of the multi-layer wafer-scale fabric ranges from below reticle size to reticle size to stitched reticle to full real estate of wafer.

12. The multi-layer wafer-scale fabric of claim 1, wherein the one or more active layers include a lithographically reconfigured circuit to compensate misalignment and modify routing.

13. A wafer-scale package comprising:
a base circuitized substrate including a first circuit and a plurality of electrical conductors;
a first integrated circuit including a second circuit and a plurality of electrical conductors;
a wafer-scale fabric including first and second opposing surfaces positioned between the base circuitized substrate and the first integrated circuit, the wafer-scale fabric electrically interconnecting selected ones of the electrical conductors of the first circuit with corresponding selected ones of the electrical conductors of the second circuit, the wafer-scale fabric including a reconfigurable logic fabric; and
at least one through Silicon via (TSV) included within the wafer-scale fabric wherein the TSV is electrically coupled to the first and second opposing surfaces of the wafer-scale fabric.

14. The wafer-scale package of claim 13, wherein the base circuitized substrate is an interposer module, a multi-chip module (MCM), a Package substrate or a printed circuit board (PCB).

15. The wafer-scale package of claim 13, wherein the reconfigurable logic fabric includes at least one transistor or junction layer.

16. The wafer-scale package of claim 13, wherein an electrical interconnect is provided from a material or combination of materials having single and/or multiple melt temperatures.

17. The wafer-scale package of claim 16, wherein the electrical interconnect is provided as a solder and/or metal ball, sphere, pillar, or micro-bump.

18. The wafer-scale package of claim 13, wherein the wafer-scale fabric is coupled to the first integrated circuit using a flip-chip bonding process, and at least one interconnect structure is provided as a metal or solder coated metal micro-bump and controls a distance and interconnect pitch between the wafer-scale fabric and integrated circuit during the flip-chip bonding process.

19. The wafer-scale package of claim 13, wherein the first integrated circuit includes at least a heat sink, micro-channel, impingement cooling or micro-jet cooling for efficient heat dissipation.

20. The wafer-scale package of claim 13, wherein the base circuitized substrate is coupled to the wafer-scale fabric using a second interconnect structure having a second, different melt temperature and larger interconnect pitch.

21. The wafer-scale package of claim 13, further comprising:
a second integrated circuit having a third circuit thereon including a plurality of electrical conductors; wherein the second integrated circuit is electrically coupled to the wafer-scale fabric.

22. The wafer-scale package of claim 21, wherein the second integrated circuit is electrically coupled to the first integrated circuit through the wafer-scale fabric.
